(19) United States
(12) Patent Application Publication
(10) Pub. No.: US 2007/0184812 A1
(43) Pub. Date: Aug. 9, 2007

(54) Cell phone dispensers

(76) Inventor: Mary Kay Bitton, Westlake Village, CA (US)

Correspondence Address: CROCKETT & CROCKETT, 24012 CALLE DE LA PLATA, SUITE 400, LAGUNA HILLS, CA, 92653, US

(21) Appl. No.: 11/703,302

(22) Filed: Feb. 6, 2007

Related U.S. Application Data
(60) Provisional application No. 60/771,118, filed on Feb. 6, 2006.

(51) Int. Cl. H05K 11/00

(52) U.S. Cl. 455/344

(57) ABSTRACT

A wireless device according to the present disclosure may accommodate one or more dispensers and or receptacles for personal care items. A wireless device may also include one or more accessories to enable the use of personal care products such as a mirror and or one or more lights. A utilitarian wireless device may enable a user to carry their wireless device and include one or more personal care products and or accessories along with their wireless device.

### FIELD OF THE INVENTION

The inventions described below relate to the field of personal care product dispensers.

### BACKGROUND OF THE INVENTIONS

The communication revolution is amply demonstrated by the increasing prevalence and use of wireless devices such as personal digital assistants and cell phones. For many people choices need to be made about how many personal items may be carried on a daily basis.

What is needed is an apparatus to enable wireless devices to host dispensers and storage sites for personal care items.

### SUMMARY

A wireless device may include one or more cavities formed to accommodate one or more dispensers and or receptacles for personal care items. A wireless device may also include one or more accessories to enable the use of personal care products such as a mirror and or one or more lights. A utilitarian wireless device may enable a user to carry their wireless device and include one or more personal care products and or accessories along with their wireless device.

Dispensers contained in a wireless device such as a cell phone may permit a user to carry medication, cosmetics or other personal care items within their wireless device. Dispensers may accommodate wand applicators, atomizers or any other suitable apparatus.

In another aspect of the present disclosure, a wireless device may provide one or more ports to accept and or engage any comparably sized or otherwise suitable dispenser.

A dispenser in a wireless device may include a hinged lid to enclose the dispenser to accommodate loose items such as but not limited to pills and or candy.

Wireless devices may be cellular telephones, personal digital assistants (PDAs) or any other wireless communication device. A wireless device may also include a cavity in a hinge, the cavity being suitable to enclose a personal care dispenser.

In still another aspect of the present disclosure, a wireless device may also include a mirror, the mirror may be protected behind a closeable lid. A mirror may also include one or more adjacent lights that may be operated from the battery of the wireless device or any other suitable energy source.

### BRIEF DESCRIPTION OF THE DRAWINGS

FIG. 1 is a front view of an open wireless device according to the present disclosure.

FIG. 2 is a side view of the wireless device of FIG. 1.

FIG. 3 is a front view of the closed wireless device of FIG. 1.

FIG. 4 is a back view of the closed wireless device of FIG. 1.

FIG. 5 is a side view of an alternate wireless device.

FIG. 6 is a front view of the door of the alternate wireless device of FIG. 5.

### DETAILED DESCRIPTION OF THE INVENTIONS

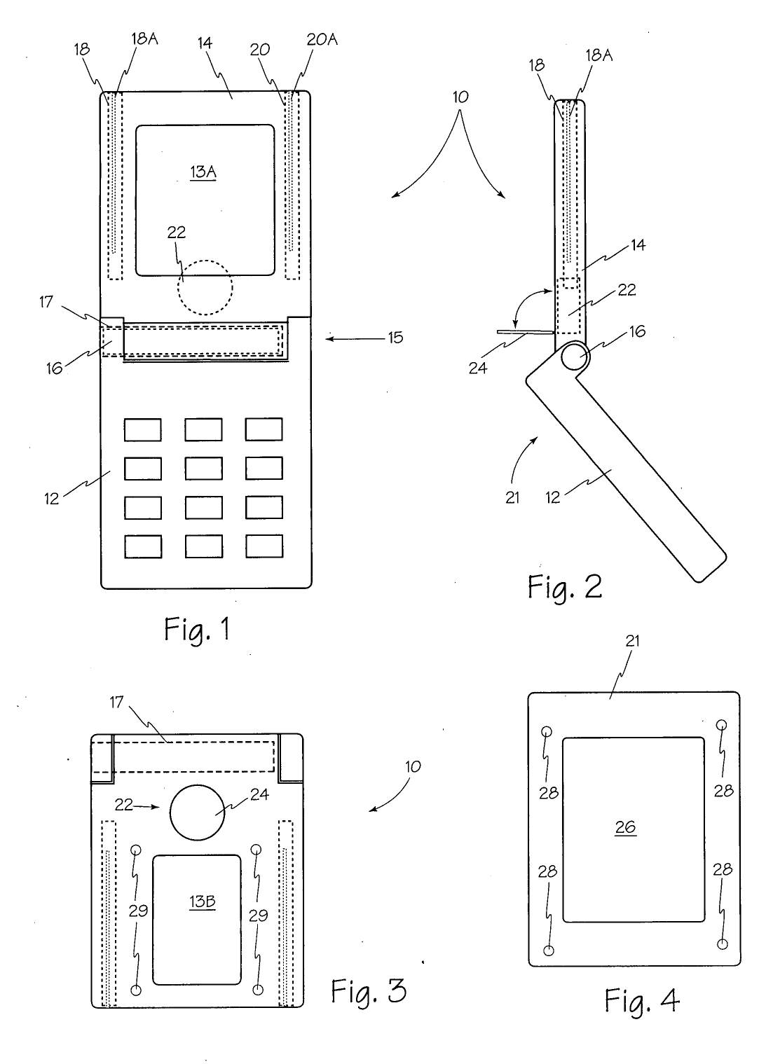

Wireless device 10 of FIG. 1 includes electronics assembly 12 and display assembly 14 secured together by hinge 15. Any other suitable configuration may also be used. Hinge 15 may include a cavity such as cavity 17 to accommodate one or more dispensers such as dispenser 16 for personal care products such as, but not limited to, lip color, gloss, balm, or other cosmetics, perfume, or medication. A wireless device such as wireless device 10 may have one or more displays such as primary display 13A and secondary display 13B.

Dispenser 16 may be an included feature of a wireless device. Alternatively, a wireless device such as wireless device 10 may include a suitable cavity such as cavity 17 to engage any suitable dispenser. Dispensers such as dispensers 18, 20 and 22 may also be included.

Any dispenser such as dispensers 18 and 20 may include a wand applicator such as applicators 18A and 20A respectively.

A dispenser such as dispenser 22 may include a cover or lid such as cover 24 shown in FIG. 2 and FIG. 3. Cover 24 is illustrated as hinged, however a cover or closure for a dispenser may adopt any suitable configuration.

Referring now to FIG. 4, back surface 21 of a wireless device such as wireless device 10 may also include accessories such as mirror 26 and one or more lights such a lights 28 to compliment the one or more personal care items that may be applied. Alternatively, one or more of the displays of a wireless device such as display 13B may include a function to set at least a substantial portion of the picture elements to a specific value that causes the display to function substantially like a mirror. Lights such as lights 29 may be included that when activated the light from lights 29 reflecting from a surface improves the apparent reflectivity of display 13B.

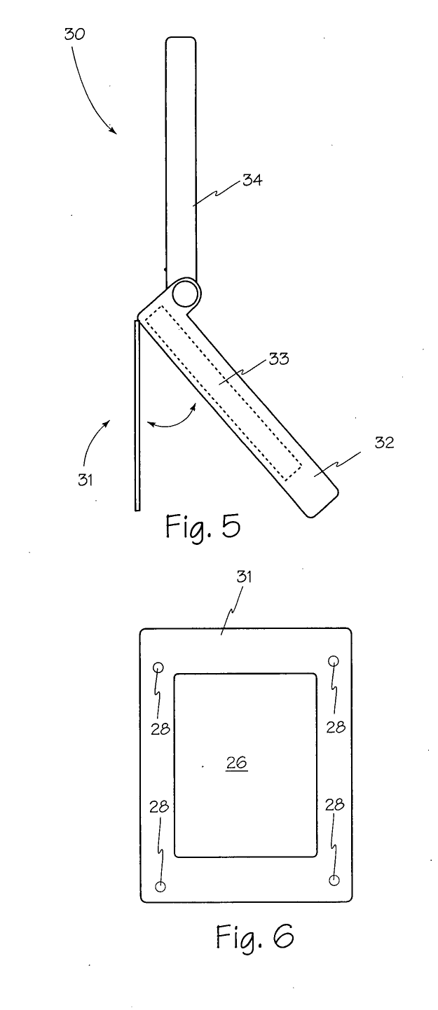

Wireless device 30 of FIG. 5 and FIG. 6 may include a deployable mirror door 31 that may shelter and or protect cavity 33 in component 32. Flip element 34 may alternatively contain a cavity and mirrored closure such as door 31. Cover 31 may include a mirror 26 and may also include one or more light elements such as lights 28.

The wireless device illustrated is presented as an example only. Any other suitable device may be used with one or more of the disclosed dispensers or any other suitable dispenser configuration.

Thus, while the preferred embodiments of the devices and methods have been described in reference to the environment in which they were developed, they are merely illustrative of the principles of the inventions. Other embodiments and configurations may be devised without departing from the spirit of the inventions and the scope of the appended claims.

I claim:

1. A device comprising:
a cellular telephone having one or more cavities to accommodate personal care products; and
one or more dispensers of personal care products, each dispenser removably engaged in a cavity in the cellular telephone.

2. The device of claim 1 further comprising:
a mirror secured to the cellular telephone, the mirror sized and oriented to facilitate application of personal care products;
one or more lights secured to the cellular telephone, the lights powered by the cellular telephone and oriented to illuminate a surface reflected by the mirror.

3. The device of claim 1 wherein a dispenser contains cosmetics.

4. The device of claim 1 wherein a dispenser contains lip balm.

5. The device of claim 1 wherein a dispenser contains perfume.

6. The device of claim 1 wherein a dispenser contains medicine.

7. The device of claim 1 wherein the cellular telephone is formed with a hinge and a cavity is in the hinge.

8. A wireless communication device comprising:
a personal digital assistant having one or more cavities to accommodate personal care products;
one or more dispensers of personal care products, each dispenser removably engaged in a cavity in the personal digital assistant;
a mirror secured to the personal digital assistant, the mirror sized and oriented to facilitate application of personal care products; and
one or more lights secured to the personal digital assistant, the lights powered by the personal digital assistant and oriented to illuminate a surface reflected by the mirror.

9. The device of claim 8 wherein a dispenser contains cosmetics.

10. The device of claim 8 wherein a dispenser contains lip balm.

11. The device of claim 8 wherein a dispenser contains perfume.

12. The device of claim 8 wherein a dispenser contains medicine.

13. The device of claim 8 wherein a dispenser contains candy.

14. The device of claim 8 wherein the personal digital assistant is formed with a hinge and a cavity is in the hinge.

15. A device comprising:
a cellular telephone; and
a mirror secured to the cellular telephone, the mirror sized and oriented to facilitate application of personal care products.

16. The device of claim 15 further comprising:
one or more lights secured to the cellular telephone, the lights powered by the cellular telephone and oriented to illuminate a surface reflected by the mirror.

17. The device of claim 15 further comprising:
one or more cavities to accommodate personal care products; and
one or more dispensers of personal care products, each dispenser removably engaged in a cavity in the cellular telephone
